(19) United States
(12) Patent Application Publication
(10) Pub. No.: US 2013/0113078 A1
(43) Pub. Date: May 9, 2013

(54) POLYSILICON-INSULATOR-SILICON CAPACITOR IN A SIGE HBT PROCESS AND MANUFACTURING METHOD THEREOF

(71) Applicants: Donghua Liu, Shanghai (CN); Wenting Duan, Shanghai (CN); Wensheng Qian, Shanghai (CN); Jun Hu, Shanghai (CN); Jing Shi, Shanghai (CN)

(72) Inventors: Donghua Liu, Shanghai (CN); Wenting Duan, Shanghai (CN); Wensheng Qian, Shanghai (CN); Jun Hu, Shanghai (CN); Jing Shi, Shanghai (CN)

(73) Assignee: SHANGHAI HUA HONG NEC ELECTRONICS CO., LTD., Shanghai (CN)

(21) Appl. No.: 13/613,209

(22) Filed: Sep. 13, 2012

(30) Foreign Application Priority Data
Nov. 3, 2011 (CN) 201110343136.9

(51) Int. Cl. H01L 29/92; H01L 21/02

(52) U.S. Cl. 257/532; 438/395; 257/E29.342; 257/E21.008

(57) ABSTRACT

A PIS capacitor in a SiGe HBT process is disclosed, wherein the PIS capacitor includes: a silicon substrate; a P-well and shallow trench isolations formed in the silicon substrate; a P-type heavily doped region formed in an upper portion of the P-well; an oxide layer and a SiGe epitaxial layer formed above the P-type heavily doped region; spacers formed on sidewalls of the oxide layer and the SiGe epitaxial layer; and contact holes for picking up the P-well and the SiGe epitaxial layer and connecting each of the P-well and the SiGe epitaxial layer to a metal wire. A method of manufacturing the PIS capacitor is also disclosed. The PIS capacitor of the present invention is manufactured by using SiGe HBT process, thus providing one more device option for the SiGe HBT process.

### CROSS-REFERENCE TO RELATED APPLICATIONS

This application claims the priority of Chinese patent application number 201110343136.9, filed on Nov. 3, 2011, the entire contents of which are incorporated herein by reference.

### TECHNICAL FIELD

The present invention relates to the field of integrated circuit manufacturing, and more particularly, to a PIS capacitor in a SiGe HBT process. The present invention also relates to a method of manufacturing PIS capacitor in a SiGe HBT process.

### BACKGROUND

Generally, PIS capacitors are manufactured by CMOS process in the prior art. In the structure of such PIS capacitors, an upper plate of the PIS capacitor may be formed by a polysilicon gate; a lower plate of the PIS capacitor may be formed by a substrate (an active region); the upper and lower plates are of the same doping type, namely both N-type or both P-type. In the CMOS process, an active region under the polysilicon gate is lightly doped (in the form of a lightly doped N-well or P-well), and an insulator such as SiO₂ or other oxides is used to separate the upper and lower plates. However, in order to reduce the effective series resistance of the capacitor, an additional implantation step is used to form a heavily doped active region of the lower plate.

With the development of the semiconductor technology, SiGe HBTs have become the main force of ultra-high-frequency devices. However, as no polysilicon gate process is included in the SiGe HBT process, a PIS capacitor that can be achieved in combination with the SiGe HBT process is desired.

### SUMMARY OF THE INVENTION

An objective of the present invention is to provide a PIS capacitor manufactured by using SiGe HBT process so as to provide one more device option for the SiGe HBT process. To this end, another objective of the present invention is to provide a method of manufacturing such a PIS capacitor in the SiGe HBT process.

To achieve the above objective, the present invention provides a PIS capacitor in a SiGe HBT process, which includes: a silicon substrate; a P-well formed in the silicon substrate; shallow trench isolations formed in the silicon substrate; a P-type heavily doped region formed in an upper portion of the P-well; wherein the P-type heavily doped region serves as one plate of the PIS capacitor; an oxide layer formed on a surface of the silicon substrate and covering part of the P-type heavily doped region; a SiGe epitaxial layer formed on the oxide layer, wherein the SiGe epitaxial layer serves as the other plate of the PIS capacitor; spacers formed on sidewalls of the oxide layer and the SiGe epitaxial layer; and contact holes for picking up the P-well and the SiGe epitaxial layer and connecting each of the P-well and the SiGe epitaxial layer to a metal wire, wherein the metal wires serves as two ends of the PIS capacitor.

To achieve the another objective, the present invention further provides a method of manufacturing PIS capacitor in a SiGe HBT process, the method including: (1) form a P-well in a silicon substrate by implantation; (2) form shallow trench isolations; (3) form a P-type heavily doped region by P-type heavily doped implantation, wherein the P-type heavily doped region serves as one plate of the PIS capacitor; (4) deposit an oxide layer; (5) grow a SiGe epitaxial layer serving as the other plate of the PIS capacitor; (6) form spacers by etch; and (7) pick up the P-well and the SiGe epitaxial layer through contact holes and connect each of the P-well and the SiGe epitaxial layer to a metal wire.

The PIS capacitor of the present invention and its manufacturing method have broken through the limitation that there is no MOS-related structure in the SiGe HBT process, and therefore has provided one more device option for the SiGe HBT process.

### BRIEF DESCRIPTION OF THE DRAWINGS

The present invention will be described and specified below in combination with accompanying drawings and exemplary embodiments.

FIG. 1 is a schematic diagram of the PIS capacitor of the present invention.

FIG. 2 is a flow chart illustrating the manufacturing method of the PIS capacitor of the present invention.

FIGS. 3 to 6 are schematic diagrams illustrating the structures of the PIS capacitor in the respective steps of the manufacturing method of the present invention.

### DETAILED DESCRIPTION

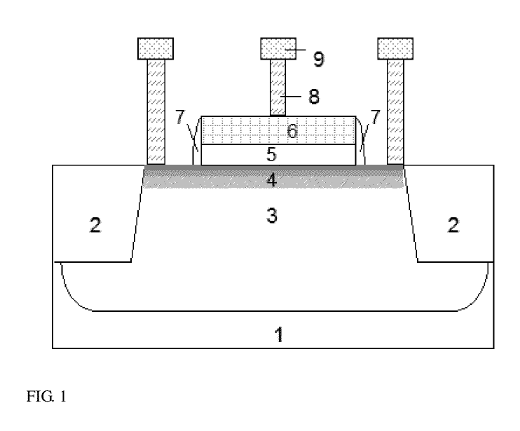

Referring to FIG. 1, the PIS capacitor of the present invention includes a silicon substrate 1, shallow trench isolations 2, a P-well 3, a P-type heavily doped region 4, an oxide layer 5, a SiGe epitaxial layer 6, spacers 7, contact holes 8 and metal wires 9. Both the shallow trench isolations 2 and the P-well 3 are formed in the silicon substrate 1; a P-type heavily doped region 4 is formed in an upper portion of the P-well 3; the shallow trench isolations 2 are adjacent to the P-well 3 and the P-type heavily doped region 4; an oxide layer 5 is formed on the P-type heavily doped region 4, and a SiGe epitaxial layer 6 is formed on the oxide layer 5; the spacers 7 are adjacent to the oxide layer 5 and the SiGe epitaxial layer 6; each of the P-well 3 and the SiGe epitaxial layer 6 is picked up through a contact hole 8 and is connecting to a metal wire 9, the metal wires 9 serve as two ends of the PIS capacitor.

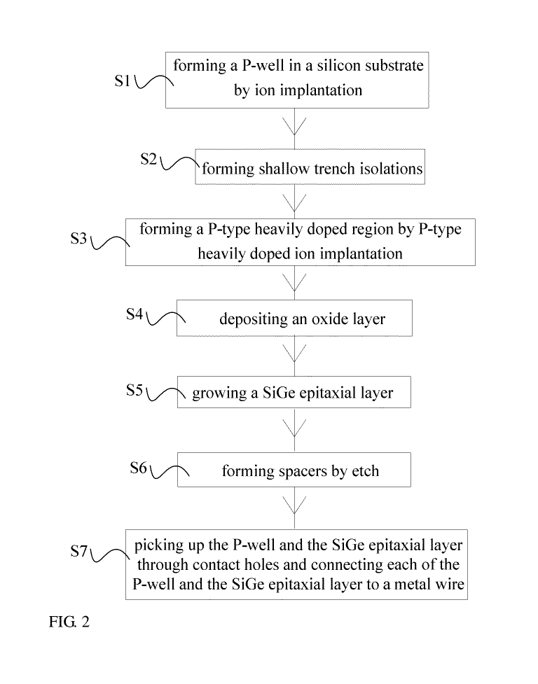

A method of manufacturing such a PIS capacitor of the present invention will be described below in combination with FIG. 2 and FIGS. 3 to 6. Referring to FIG. 2, the method includes the following steps:

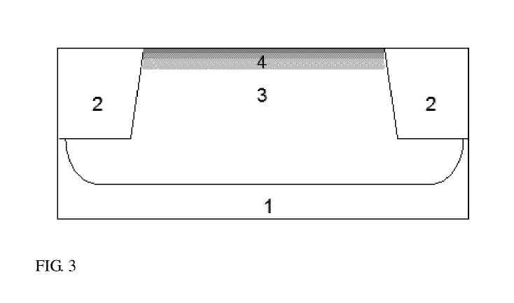

Step S1: as shown in FIG. 3, form a P-well 3 in a silicon substrate 1 by ion implantation, wherein the impurity implanted may be boron; an energy of the implantation may be from 50 KeV to 500 KeV; and a dose of the implantation may be from 5e11 cm⁻² to 5e13 cm⁻²;

Step S2: form shallow trench isolations 2 in the silicon substrate 1;

Step S3: perform heavily doped ion implantation beneath a surface of the silicon substrate 1 to form a P-type heavily doped region in an upper portion of the P-well 3, wherein the impurity implanted may be boron or boron fluoride; an energy of the implantation may be from 5 KeV to 50 KeV; and a dose of the implantation may be from 5e14 cm⁻²to 1e17 cm⁻²;

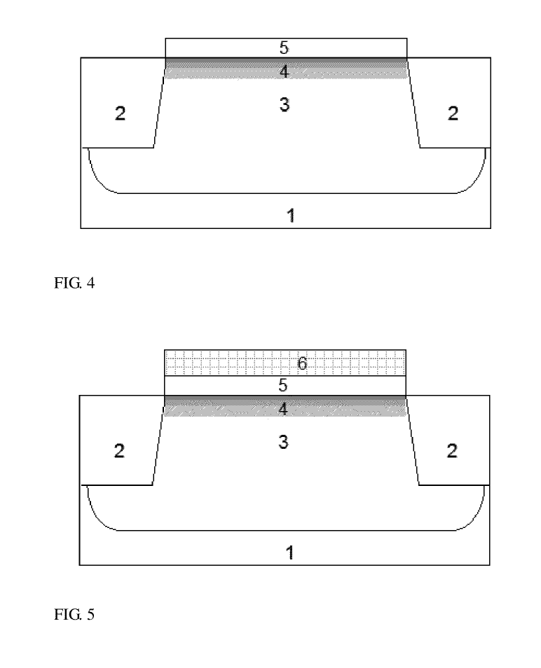

Step S4: as shown in FIG. 4, deposit an oxide layer 5 on the surface of the silicon substrate 1, the oxide layer may have a thickness of from 5 nm to 30 nm;

Step S5: as shown in FIG. 5, grow a P-doped SiGe epitaxial layer 6 on the oxide layer 5, wherein the P-type impurity may be boron or boron fluoride; an energy of the doping is from 5 KeV to 100 KeV; and a dose of the doping is from 1e14 cm⁻²to 1e17 cm⁻².

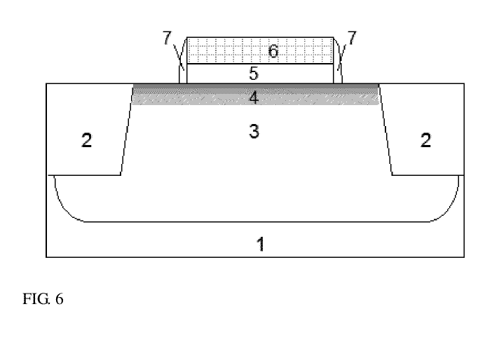

Step S6: as shown in FIG. 6, remove part of the SiGe epitaxial layer 6 and part of the oxide layer 5 by etch to expose part of the P-type heavily doped region 4, the exposed part of the P-type heavily doped region 4 is at two sides of the oxide layer 5 and the SiGe epitaxial layer 6; and then form spacers 7 on sidewalls of the oxide layer 5 and the SiGe epitaxial layer 6;

Step S7: pick up the P-well 3 and the SiGe epitaxial layer 6 through contact holes 8 and connect each of the P-well 3 and the SiGe epitaxial layer 6 to a metal wire 9, so as to form the PIS capacitor as shown in FIG. 1.

The above embodiments are provided for the purpose of describing the invention and are not intended to limit the scope of the invention in any way. It will be apparent to those skilled in the art that various modifications and variations can be made without departing from the spirit or scope of the invention. Thus, it is intended that the present invention cover the modifications and variations of this invention.

What is claimed is:

1. A PIS capacitor in a SiGe HBT process, comprising:
a silicon substrate;
a P-well formed in the silicon substrate;
shallow trench isolations formed in the silicon substrate;
a P-type heavily doped region formed in an upper portion of the P-well, the P-type heavily doped region serving as a lower plate of the PIS capacitor;
an oxide layer formed on a surface of the silicon substrate and covering part of the P- type heavily doped region;
a SiGe epitaxial layer formed on the oxide layer, the SiGe epitaxial layer serving as an upper plate of the PIS capacitor;
spacers formed on sidewalls of the oxide layer and the SiGe epitaxial layer; and
contact holes for picking up the P-well and the SiGe epitaxial layer and connecting each of the P-well and the SiGe epitaxial layer to a metal wire, the metal wires serving as two ends of the PIS capacitor.

2. The PIS capacitor according to claim 1, wherein the P-well is formed by using boron as a P-type impurity.

3. The PIS capacitor according to claim 1, wherein the P-type heavily doped region is formed by using boron or boron fluoride as a P-type impurity.

4. The PIS capacitor according to claim 1, wherein the SiGe epitaxial layer is a P-doped SiGe epitaxial layer doped by using boron or boron fluoride as the P-type impurity.

5. The PIS capacitor according to claim 1, wherein the oxide layer has a thickness of from 5 nm to 30 nm.

6. A method of manufacturing the PIS capacitor according to claim 1, comprising:
forming a P-well in a silicon substrate by P-type ion implantation;
forming shallow trench isolations in the silicon substrate;
performing P-type heavily doped ion implantation beneath a surface of the silicon substrate to form a P-type heavily doped region in an upper portion of the P-well, the P-type heavily doped region serving as a lower plate of the PIS capacitor;
depositing an oxide layer on the surface of the silicon substrate;
growing a SiGe epitaxial layer on the oxide layer, the SiGe epitaxial layer serving as an upper plate of the PIS capacitor;
removing part of the SiGe epitaxial layer and part of the oxide layer by etch to expose part of the P-type heavily doped region;
forming spacers on sidewalls of the oxide layer and the SiGe epitaxial layer; and
picking up the P-well and the SiGe epitaxial layer through contact holes and connecting each of the P-well and the SiGe epitaxial layer to a metal wire.

7. The method according to claim 6, wherein the P-type ion implantation for forming the P-well is carried out in conditions as follows: the P-type impurity is boron; an energy of the implantation is from 50 KeV to 500 KeV; a dose of the implantation is from 5e11 cm⁻²to 5e13 cm⁻².

8. The method according to claim 6, wherein the P-type heavily doped ion implantation for forming the P-type heavily doped region is carried out in conditions as follows: the P-type impurity is boron or boron fluoride; an energy of the implantation is from 5 KeV to 50 KeV; a dose of the implantation is from 5e14 cm⁻²to 1e17 cm⁻².

9. The method according to claim 6, wherein after the step of growing the SiGe epitaxial layer on the oxide layer, further comprising: performing P-type doping to the SiGe epitaxial layer, wherein the P-type impurity is boron or boron fluoride; an energy of the doping is from 5 KeV to 100 KeV; a dose of the doping is from 1e14 cm⁻²to 1e17 cm ⁻².
